(19) United States
(12) Patent Application Publication
(10) Pub. No.: US 2008/0310215 A1
(43) Pub. Date: Dec. 18, 2008

(54) MAGNETIC RANDOM ACCESS MEMORY AND WRITE METHOD OF THE SAME

(76) Inventor: Yoshihiro Ueda, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/138,017

(22) Filed: Jun. 12, 2008

(30) Foreign Application Priority Data
Jun. 13, 2007 (JP) 2007-156576

(51) Int. Cl. G11C 11/00; G11C 7/00

(52) U.S. Cl. 365/158; 365/171; 365/189.16

(57) ABSTRACT

A magnetic random access memory includes a memory unit including a memory cell array having a first memory cell for writing first information and a second memory cell for writing second information, and a controller connected to the memory unit, and configured to start supplying a write current in a first direction for writing the first information to the first memory cell and the second memory cell before a write data signal is determined, and, after the write data signal is determined, keep supplying the write current in the first direction to the first memory cell and supply the write current changed in a second direction for writing the second information to the second memory cell alone.

### CROSS-REFERENCE TO RELATED APPLICATIONS

This application is based upon and claims the benefit of priority from prior Japanese Patent Application No. 2007-156576, filed Jun. 13, 2007, the entire contents of which are incorporated herein by reference.

### BACKGROUND OF THE INVENTION

1. Field of the Invention

The present invention relates to a spin transfer torque magnetization switching type magnetic random access memory and a write method of the same.

2. Description of the Related Art

A magnetoresistive random access memory (MRAM) uses a magnetoresistive effect element as a memory cell. The magnetoresistive effect element includes a free layer (recording layer) in which the magnetization direction is variable, a fixed layer in which the magnetization direction is fixed, and a nonmagnetic layer sandwiched between them. The magnetoresistive effect element takes a low-resistance state when the magnetization direction in the free layer is parallel to that in the fixed layer, and a high-resistance state when the former is antiparallel to the latter. Information is recorded by using this difference between the resistance states.

Information is read out by supplying a read current to the magnetoresistive effect element, and comparing a current value or voltage value cased by the resistance state with a reference value, thereby discriminating the resistance state.

Information is written by one of the magnetic field writing method and spin transfer torque magnetization reversing method (e.g., patent reference 1 and non-patent reference 1). In the magnetic field writing method, magnetization in the free layer is reversed by applying, to the free layer, a magnetic field generated by electric currents flowing through two write lines perpendicular to each other. A memory cell array is formed by arranging such memory cells. On the other hand, in the spin transfer torque magnetization reversing method, the magnetization direction in the free layer is changed by supplying, to the free layer, an electric current spin-polarized by the magnetic moment in the fixed layer.

The spin transfer torque magnetization reversing method can act on a nanoscale magnetic material more directly than the magnetic field writing method. Accordingly, no write error occurs in adjacent memory cells, and high-speed magnetization reversal can be expected. The spin transfer torque magnetization reversing method also has the advantage that the amount of electric current necessary for a write operation reduces as the cell size decreases.

In the spin transfer torque magnetization reversing method, however, the amount of electric current that can be supplied to a memory cell is limited because a selection transistor is connected in series with the magnetoresistive effect element. To supply an electric current sufficient to perform a write operation, therefore, a gate width W of the selection transistor must be increased. This increases the memory cell size, and makes it difficult to increase the degree of integration.

[Patent reference 1] U.S. Pat. No. 5,695,864

[Non-patent reference 1] M. Hosomi et al., “A Novel Nonvolatile Memory with Spin Torque Transfer Magnetization Switching Spin-RAM”, IEDM Tech. Dig., 2005, pp. 459-462.

### BRIEF SUMMARY OF THE INVENTION

A magnetic random access memory according to the first aspect of the present invention comprising: a memory unit including a memory cell array having a first memory cell for writing first information and a second memory cell for writing second information; and a controller connected to the memory unit, and configured to start supplying a write current in a first direction for writing the first information to the first memory cell and the second memory cell before a write data signal is determined, and, after the write data signal is determined, keep supplying the write current in the first direction to the first memory cell and supply the write current changed in a second direction for writing the second information to the second memory cell alone.

A write method of a magnetic random access memory according to the second aspect of the present invention including: a memory unit including a memory cell array having a first memory cell for writing first information and a second memory cell for writing second information; and a controller connected to the memory unit, the write method comprising: starting supplying a write current in a first direction for writing the first information to the first memory cell and the second memory cell, before a write data signal is determined; and after the write data signal is determined, keeping supplying the write current in the first direction to the first memory cell, and supplying the write current changed in a second direction for writing the second information to the second memory cell alone.

### BRIEF DESCRIPTION OF THE SEVERAL VIEWS OF THE DRAWING

FIG. 1 is a schematic block diagram of a magnetic random access memory according to an embodiment of the present invention;

FIG. 2 is a schematic view of a memory unit according to the embodiment of the present invention;

FIG. 3 is a sectional view of a magnetoresistive effect element according to the embodiment of the present invention;

FIG. 4A is a sectional view of a parallel state of the magnetoresistive effect element according to the embodiment of the present invention;

FIG. 4B is a sectional view of an antiparallel state of the magnetoresistive effect element according to the embodiment of the present invention;

FIG. 5 is a timing chart of write method example 1 according to the embodiment of the present invention;

FIGS. 6A and 6B are exemplary views showing a write current supply method of write method example 1 according to the embodiment of the present invention;

FIG. 7 is a timing chart of write method example 2 according to the embodiment of the present invention;

FIGS. 8A and 8B are exemplary views showing a write current supply method of write method example 2 according to the embodiment of the present invention; and

FIG. 9 is a graph showing the dependence of a reversing current on the write time in the magnetoresistive effect element according to the embodiment of the present invention.

### DETAILED DESCRIPTION OF THE INVENTION

An embodiment of the present invention will be explained below with reference to the accompanying drawing. In the following explanation, the same reference numerals denote the same parts throughout the drawing.

### [1] Arrangement of Magnetic Random Access Memory

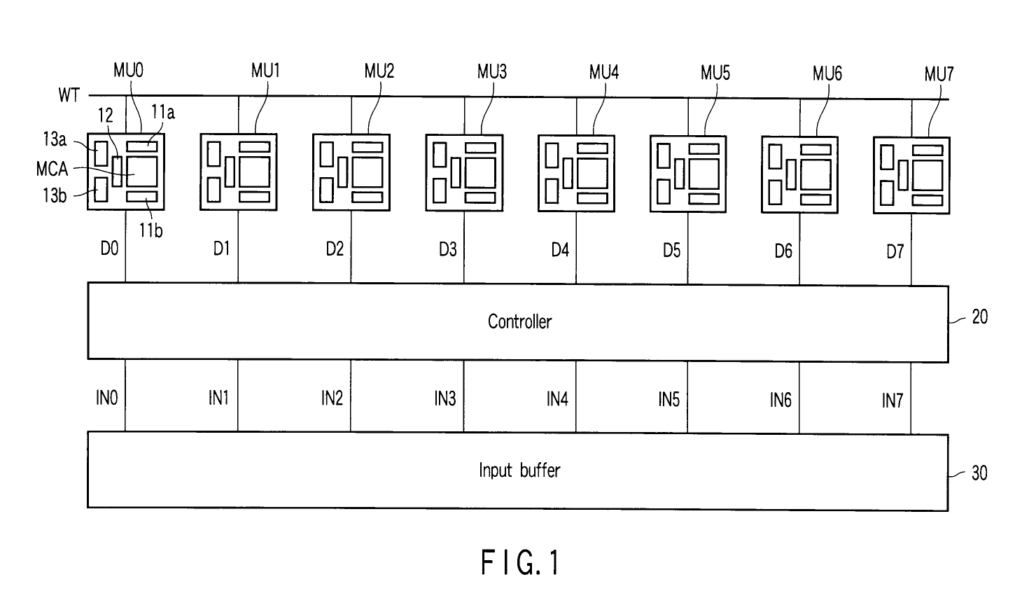

FIG. 1 is a schematic block diagram of a magnetic random access memory according to the embodiment of the present invention. An outline of the arrangement of the magnetic random access memory will be explained below.

As shown in FIG. 1, the magnetic random access memory comprises memory units MUn (n=0 to 7), a controller 20, and an input buffer 30.

The memory units MUn each have a memory cell array MCA, column decoders 11a and 11b, a row decoder 12, and write driver circuits 13a and 13b. The memory units MUn are connected to the input buffer 30 via the controller 20. A common write activation signal WT is supplied to the memory units MUn. The controller 20 supplies different write data signals Dn (n=0 to 7) to the memory units MUn. Note that the number of the memory units MUn is eight in this embodiment, but the number of the units can be increased or decreased.

The controller 20 receives input data signals INn (n=0 to 7) for a write operation from the input buffer 30, and supplies the write data signals Dn to the memory units MUn.

The input buffer 30 holds the input data signals INn, and supplies the input data signals INn to the controller 20.

### [2] Memory Unit

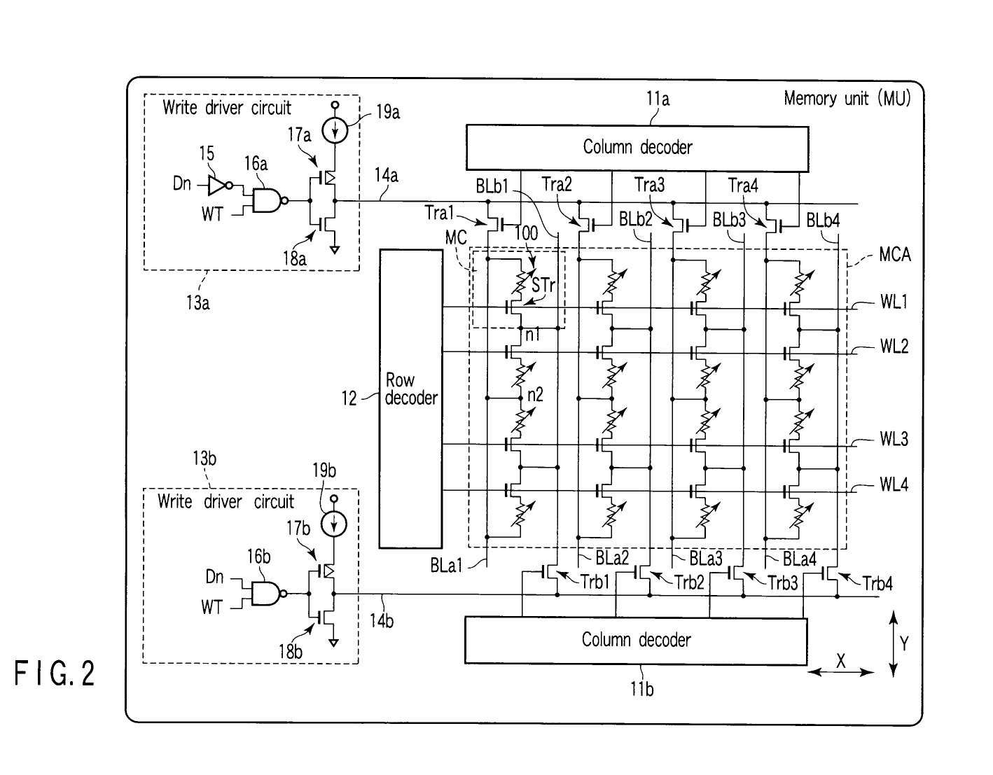

FIG. 2 is a schematic view of the memory unit according to the embodiment of the present invention. An outline of the arrangement of the memory unit will be explained below by taking a memory cell MC shown in FIG. 2 as an example. Note that the memory unit shown in FIG. 2 corresponds to one memory unit shown in FIG. 1.

As shown in FIG. 2, the memory unit MU comprises the memory cell array MCA, first and second bit lines BLan and BLbn (n=1 to 4), word lines WLn (n=1 to 4), the first and second column decoders 11a and 11b, the row decoder 12, the first and second write driver circuits 13a and 13b, first and second column selection pass transistors Tran and Trbn (n=1 to 4), and first and second common lines 14a and 14b.

The memory cell array MCA is formed by arranging memory cells MC in a matrix. The column decoders 11a and 11b and row decoder 12 select the memory cell MC. The memory cell MC comprises a magnetoresistive effect element 100 and cell selection transistor STr connected in series. The magnetoresistive effect element 100 is, e.g., an MTJ (Magnetic Tunnel Junction) element.

One terminal of the magnetoresistive effect element 100 is connected to one end of the current path (source/drain) of the transistor STr. The other terminal of the magnetoresistive effect element 100 is connected to the first bit line BLa1. The other end of the current path of the transistor STr is connected to the second bit line BLb1. The gate of the transistor STr is connected to the word line WL1.

The relationships between the memory cells MC are as follows.

The memory cells MC adjacent to each other in the X direction share the same word line WLn. For example, as shown in FIG. 2, the gates of the transistors STr adjacent to each other in the X direction are connected to the word line WL1.

In the memory cells MC adjacent to each other in the Y direction, the ends of the current paths of the transistors STr or the terminals of the magnetoresistive effect elements 100 are connected, and these two connection relationships alternately exist. For example, as shown in FIG. 2, a node n1 connects the current paths of the transistors STr adjacent to each other in the Y direction, and is connected to the second bit line BLb1. More specifically, the adjacent transistors STr share the source/drain diffusion layer, and this shared diffusion layer is connected to the second bit line BLb1 by a contact. Also, as shown in FIG. 2, a node n2 connects the terminals of the magnetoresistive effect elements 100 adjacent to each other in the Y direction, and is connected to the first bit line BLa1.

One end of the first bit line BLa1 is connected to one end of the current path of the first pass transistor Tra1. The other end of the current path of the pass transistor Tra1 is connected to the first common line 14a. The gate of the first pass transistor Tra1 is connected to the first column decoder 11a. Accordingly, the first column decoder 11a drives the first pass transistor Tra1. The first common line 14a is connected to the first write driver circuit 13a.

One end of the second bit line BLb1 is connected to one end of the current path of the second pass transistor Trb1. The other end of the current path of the second pass transistor Trb1 is connected to the second common line 14b. The gate of the second pass transistor Trb1 is connected to the second column decoder 11b. Therefore, the second column decoder 11b drives the second pass transistor Trb1. The second common line 14b is connected to the second write driver circuit 13b.

One end of the word line WL1 is connected to the row decoder 12 in the periphery of the memory cell array MCA. Accordingly, the row decoder 12 drives the transistor STr of the memory cell MC via the word line WL1.

The first write driver 13a includes a current source, a current sink, and a control circuit for exclusively validating the current source and current sink. More specifically, the first write driver circuit 13a has an inverter 15, NAND circuit 16a, PMOS transistor 17a, NMOS transistor 18a, and current source 19a. The output terminal of the inverter 15 is connected to one input terminal of the NAND circuit 16a, and the output terminal of the NAND circuit 16a is connected to the gates of the PMOS transistor 17a and NMOS transistor 18a. One end of the current path of each of the PMOS transistor 17a and NMOS transistor 18a is connected to the common line 14a. The other end of the current path of the PMOS transistor 17a is connected to the current source 19a. In the first write driver circuit 13a like this, the controller 20 shown in FIG. 1 inputs the write data signal Dn to the input terminal of the inverter 15. An output signal from the inverter 15 and the write activation signal WT are input to the input terminals of the NAND circuit 16a.

The second write driver 13b includes a current source, a current sink, and a control circuit for exclusively validating the current source and current sink. More specifically, the second write driver circuit 13b has a NAND circuit 16b, PMOS transistor 17b, NMOS transistor 18b, and current source 19b. The output terminal of the NAND circuit 16b is connected to the gates of the PMOS transistor 17b and NMOS transistor 18b. One end of the current path of each of the PMOS transistor 17b and NMOS transistor 18b is connected to the common line 14b. The other end of the current path of the PMOS transistor 17b is connected to the current source 19b. In the second write driver circuit 13b like this, the write data signal Dn and write activation signal WT are input to the input terminals of the NAND circuit 16b.

When the write activation signal WT of the first and second write driver circuits 13a and 13b is inactive, the first and second write driver circuits 13a and 13b function as current sinks, and set the first and second common lines 14a and 14b at a fixed potential (e.g., the ground potential). On the other hand, when the write activation signal WT of the first and second write driver circuits 13a and 13b is active, the first and second write driver circuits 13a and 13b each function as a current source or current sink in accordance with the logic of the write data signal Dn. Note that in this case, one of the first and second write driver circuits 13a and 13b functions as a current source and the other functions as a current sink for the same logic of the write data signal Dn.

### [3] Magnetoresistive Effect Element

### [3-1] Structure

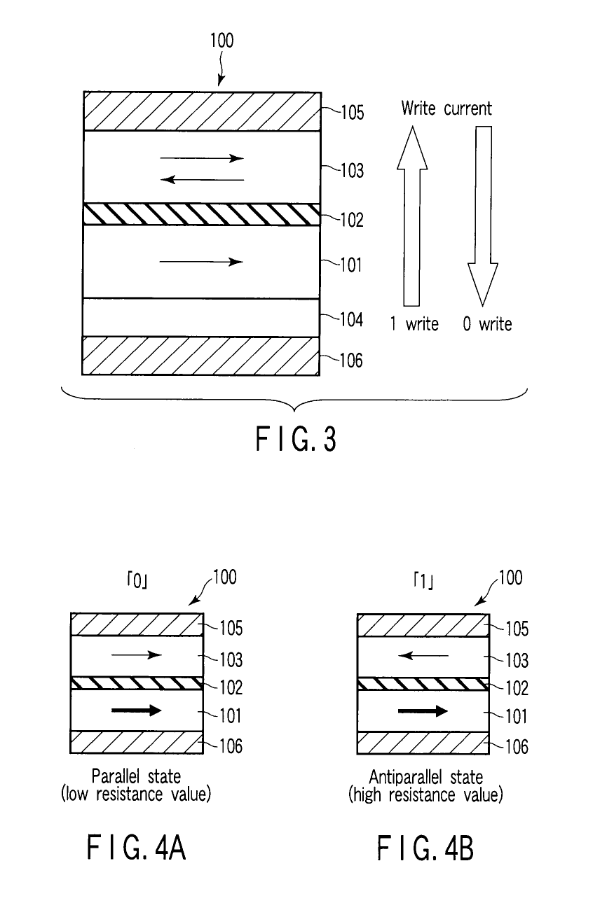

FIG. 3 is a sectional view of the magnetoresistive effect element according to the embodiment of the present invention. The structure of the magnetoresistive effect element will be explained below.

The magnetoresistive effect element 100 can take two steady states in accordance with the spin transfer torque magnetization reversing method. More specifically, as shown in FIG. 3, the magnetoresistive effect element 100 has at least a fixed layer 101, a free layer (recording layer) 103, and an interlayer 102 formed between the fixed layer 101 and free layer 103. It is also possible to form an upper electrode 105 on that surface of the free layer 103 which is away from the interlayer 102, and a lower electrode 106 on that surface of an antiferromagnetic layer 104 which is away from the fixed layer 101.

The fixed layer 101 is made of a ferromagnetic material, and has a fixed magnetization direction. For example, magnetization in the fixed layer 101 can be fixed by forming the antiferromagnetic layer 104 on that surface of the fixed layer 101 which is away from the interlayer 102.

The free layer 103 is made of a ferromagnetic material. No such fixing mechanism as that for the fixed layer 101 is formed for the magnetization direction in the free layer 103. Therefore, the magnetization direction in the free layer 103 is variable.

The interlayer 102 is made of a nonmagnetic material. The interlayer 102 desirably has a film thickness that spaces the fixed layer 101 and free layer 103 apart from each other to such an extent that the direct interaction acting between the fixed layer 101 and free layer 103 is negligible. At the same time, the film thickness of the interlayer 102 is desirably smaller than the spin diffusion length because when a write current is supplied to the magnetoresistive effect element 100, conduction electrons transmitted through the fixed layer 101 must not reverse the spin direction before reaching the free layer 103. As the interlayer 102, it is possible to use, e.g., a nonmagnetic metal, nonmagnetic semiconductor, or insulating film.

Note that each of the fixed layer 101 and free layer 103 is not limited to a single layer as shown in FIG. 3. For example, at least one of the fixed layer 101 and free layer 103 may also have a stacked structure including a plurality of ferromagnetic layers.

In addition, at least one of the fixed layer 101 and free layer 103 may also have an antiferromagnetic coupling structure which includes three layers, i.e., a first ferromagnetic layer/nonmagnetic layer/second ferromagnetic layer, and in which the first and second ferromagnetic layers are magnetically coupled (by interlayer exchange coupling) so that their magnetization directions are antiparallel, or a ferromagnetic coupling structure in which the first and second ferromagnetic layers are magnetically coupled (by interlayer exchange coupling) so that their magnetization directions are parallel.

A double-junction structure may also be used. A magnetoresistive effect element having the double-junction structure includes a first fixed layer, a second fixed layer, a free layer, a first interlayer formed between the first fixed layer and free layer, and a second interlayer formed between the second fixed layer and free layer. Compared to a single-junction structure, the double-junction structure has the advantage that it is possible to further increase the ratio of a resistance value in a low-resistance state to that in a high-resistance state, i.e., a so-called MR ratio (Magneto-Resistance ratio).

### [3-2] Practical Examples of Materials

As the ferromagnetic material of the fixed layer 101 and free layer 103, it is possible to use, e.g., Co, Fe, Ni, or an alloy containing any of these metals.

When using a nonmagnetic metal as the interlayer 102, it is possible to use any of Au, Cu, Cr, Zn, Ga, Nb, Mo, Ru, Pd, Ag, Hf, Ta, W, Pt, and Bi, or an alloy containing at least one of these metals. Note that when allowing the interlayer 102 to function as a tunnel barrier layer, it is possible to use an insulating oxide such as Al₂O₃, SiO₂, MgO, or AlN.

As the material of the antiferromagnetic layer 104, it is possible to use, e.g., Fe—Mn, Pt—Mn, Pt—Cr—Mn, Ni—Mn, Pd—Mn, NiO, Fe₂O₃, or a magnetic semiconductor.

### [3-3] Parallel and Antiparallel Magnetization Configurations

FIGS. 4A and 4B are sectional views showing the parallel and antiparallel states of the magnetoresistive effect element according to the embodiment of the present invention. The parallel and antiparallel magnetization configurations of the magnetoresistive effect element resulting from spin transfer torque write will be explained below.

When reversing the magnetization direction in the free layer 103 which is antiparallel to that in the fixed layer 101, thereby making the former parallel to the latter, an electron flow is supplied from the fixed layer 101 to the free layer 103. Generally, many electrons in an electron flow passing through a certain magnetic material have spins parallel to the magnetization direction in this magnetic material. Therefore, many electrons in the electron flow passing through the fixed layer 101 have spins parallel to the magnetization direction in the fixed layer 101. This electron flow mainly contributes to the torque acting on magnetization in the free layer 103. Not that the rest of electrons in the electron flow have spins antiparallel to the magnetization direction in the fixed layer 101.

On the other hand, when reversing magnetization in the free layer 103 which is parallel to the magnetization direction in the fixed layer 101, thereby making the former antiparallel to the latter, an electron flow is supplied from the free layer 103 to the fixed layer 101. This electron flow is transmitted through the free layer 103, and many electrons having spins antiparallel to the magnetization direction in the fixed layer 101 are reflected by the fixed layer 101, and return to the free layer 103. These electrons having spins antiparallel to the magnetization direction in the fixed layer 101 flow into the free layer 103 again, and mainly contribute to the torque acting on magnetization in the free layer 103. Note that some electrons transmitted through the free layer 103 and having spins antiparallel to the magnetization direction in the fixed layer 101 are transmitted through the fixed layer 101, although the number of these electrons is small.

In the spin transfer torque write described above, the resistance state of the magnetoresistive effect element 100 is made to correspond to the logic to be stored. That is, the case where the magnetization directions in the fixed layer 101 and free layer 103 are parallel (the low-resistance state) is regarded as “0” as shown in FIG. 4A, and the case where the magnetization directions in the fixed layer 101 and free layer 103 are antiparallel (the high-resistance state) is regarded as “1” as shown in FIG. 4B.

### [3-4] Magnetization Arrangement

The magnetization directions in the fixed layer 101 and free layer 103 of the magnetoresistive effect element 100 can be perpendicular to the film surfaces (a perpendicular magnetization type element), and parallel to the film surfaces (an in-plane magnetization type element or parallel magnetization type element).

Note that the perpendicular magnetization type element is suitable for micropatterning because the element shape need not be controlled in order to determine the magnetization direction unlike in the in-plane magnetization type element.

### [4] Write Operation

### [4-1] Reference Example

First, the process of a normal write method will be explained below as a reference example with reference to FIG. 1.

(1) The input data signals IN0 to IN7 are determined and held in the input buffer 30.

(2) The input buffer 30 inputs the input data signals IN0 to IN7 to the controller 20, and the controller 20 directly supplies the logic levels of the input data signals IN0 to IN7 as the write data signals D0 to D7 to the memory units MU0 to MU7.

(3) Write currents are supplied to the memory cells MC in the memory units MU0 to MU7 by activating the write activation signal WT, thereby writing data in the magnetoresistive effect elements 100.

(4) The supply of the write currents is stopped by inactivating the write activation signal WT.

In the write method of the reference example as described above, the write activation signal WT is not supplied to the memory cells MC and no write is started until the write data signals D0 to D7 are determined.

### [4-2] Write Method Example 1

Write method example 1 decreases a reversing current for 1 write by increasing the supply time of a write current for 1 write.

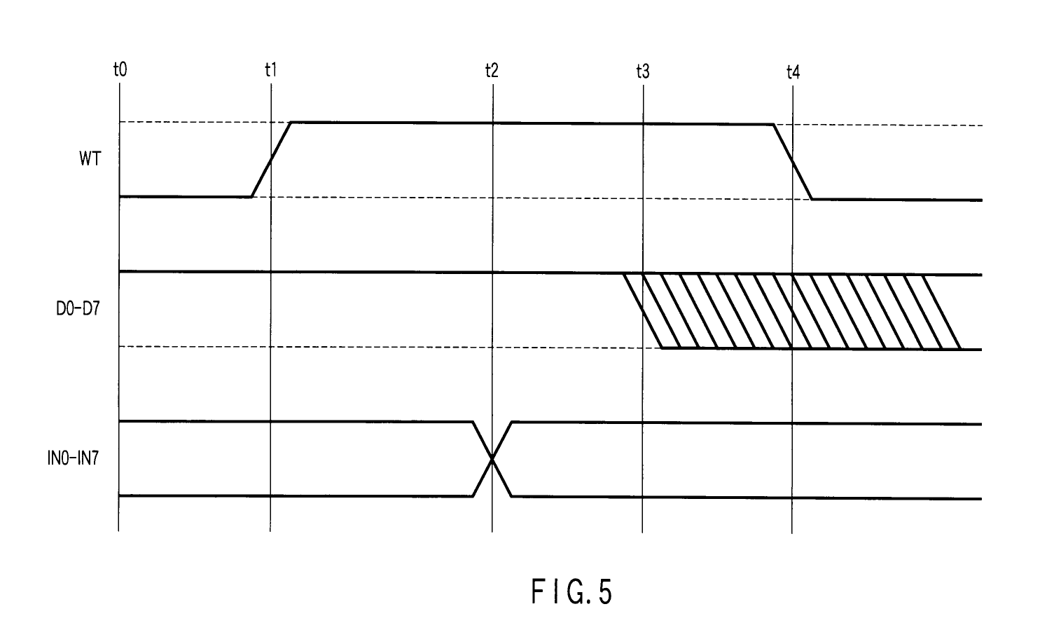

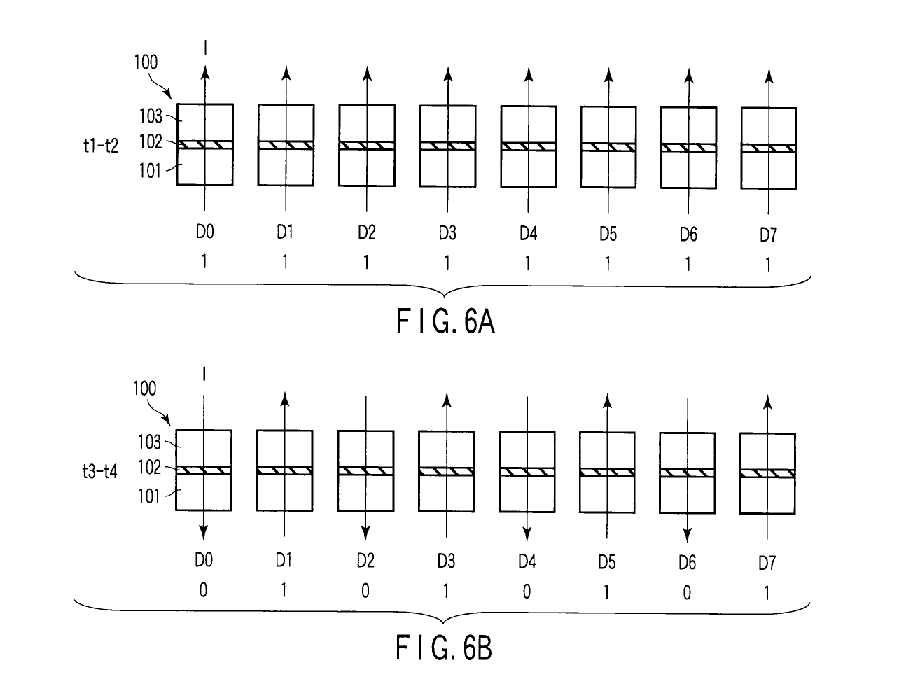

FIG. 5 is a timing chart of write method example 1 according to the embodiment of the present invention. FIGS. 6A and 6B are views for explaining a practical method of write method example 1 according to the embodiment of the present invention. Write method example 1 will be explained below with reference to FIGS. 1, 5, 6A, and 6B.

(1) Time t0

At time t0, the controller 20 sets all the write data signals D0 to D7 in a logic 1 state.

(2) Time t1

At time t1, the write driver circuits 13a and 13b activate the write activation signal WT, thereby starting supplying write currents for 1 write to all the memory units MU0 to MU7.

(3) Time t2

At time t2, the input data signals IN0 to IN7 are determined, and the input buffer 30 supplies the input data signals IN0 to IN7 to the controller 20.

(4) Time t3

At time t3, the controller 20 outputs the write data signals D0 to D7 corresponding to the logic levels of the input data signals IN0 to IN7. Accordingly, the direction of the write current of a memory unit in which 1 is to be written remains unchanged, and only the direction of the write current of a memory unit in which 0 is to be written reverses.

(5) Time t4

At time t4, the write driver circuits 13a and 13b inactivate the write activation signal WT, thereby stopping the supply of the write currents.

When writing, e.g., “01010101” in the memory units MU0 to MU7 in write method example 1 as described above, the directions of write currents I from time t1 to time t4 are as shown in FIGS. 6A and 6B.

First, between time t1 and time t2 as shown in FIG. 6A, write currents I for 1 write are supplied to all the memory units MU0 to MU7. That is, the write current I is supplied from the fixed layer 101 to the free layer 103 (an electron flow is supplied from the free layer 103 to the fixed layer 101) in all the magnetoresistive effect elements 100 of the memory units MU0 to MU7.

Then, between time t3 and time t4 as shown in FIG. 6B, write currents I for 0 write are supplied to only four memory units, i.e., the memory units MU0, MU2, MU4, and MU6 in which 0 is to be written. That is, while the write currents I for 1 write are kept supplied to the memory units MU1, MU3, MU5, and MU7 in which 1 is to be written, only the write currents I in the memory units MU0, MU2, MU4, and MU6 in which 0 is to be written are supplied in the opposite direction.

### [4-3] Write Method Example 2

Write method example 2 decreases a reversing current for 0 write by increasing the supply time of a write current for 0 write.

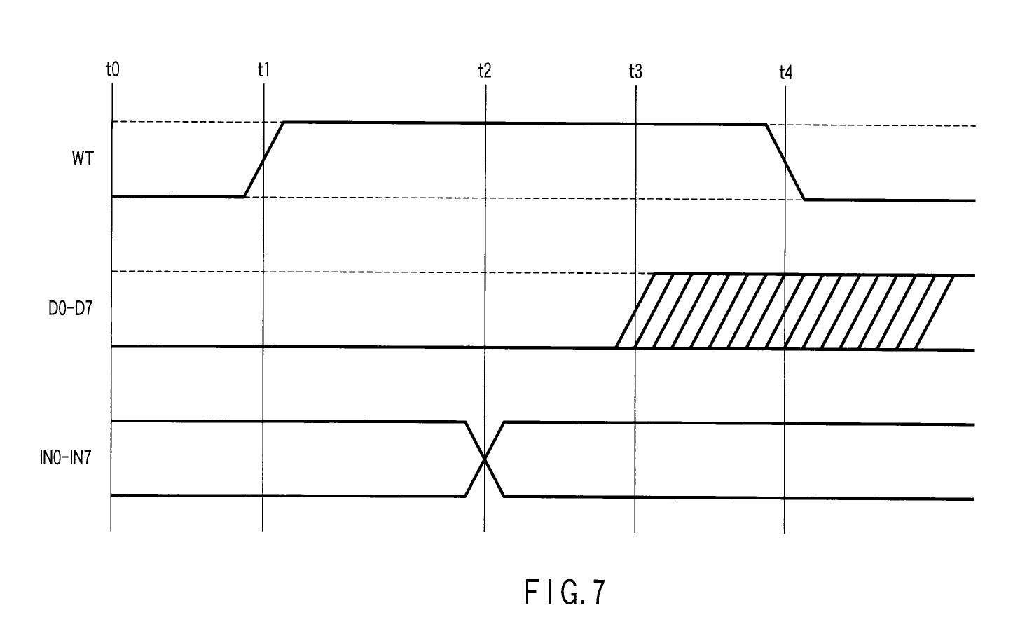

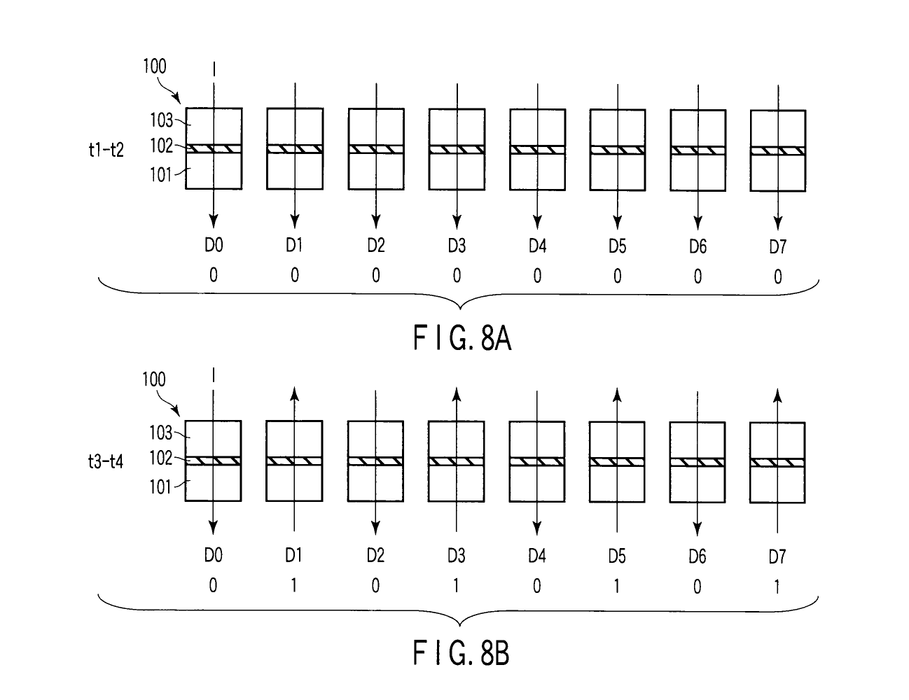

FIG. 7 is a timing chart of write method example 2 according to the embodiment of the present invention. FIGS. 8A and 8B are views for explaining a practical method of write method example 2 according to the embodiment of the present invention. Write method example 2 will be explained below with reference to FIGS. 1, 7, 8A, and 8B.

(1) Time t0

At time t0, the controller 20 sets all the write data signals D0 to D7 in a logic 0 state.

(2) Time t1

At time t1, the write driver circuits 13a and 13b activate the write activation signal WT, thereby starting supplying write currents for 0 write to all the memory units MU0 to MU7.

(3) Time t2

At time t2, the input data signals IN0 to IN7 are determined, and the input buffer 30 supplies the input data signals IN0 to IN7 to the controller 20.

(4) Time t3

At time t3, the controller 20 outputs the write data signals D0 to D7 corresponding to the logic levels of the input data signals IN0 to IN7. Accordingly, the direction of the write current of a memory unit in which 0 is to be written remains unchanged, and only the direction of the write current of a memory unit in which 1 is to be written reverses.

(5) Time t4

At time t4, the write driver circuits 13a and 13b inactivate the write activation signal WT, thereby stopping the supply of the write currents.

When writing, e.g., “01010101” in the memory units MU0 to MU7 in write method example 2 as described above, the directions of the write currents I are as shown in FIGS. 8A and 8B.

First, between time t1 and time t2 as shown in FIG. 8A, the write currents I for 0 write are supplied to all the memory units MU0 to MU7. That is, the write current I is supplied from the free layer 103 to the fixed layer 101 (an electron flow is supplied from the fixed layer 101 to the free layer 103) in all the magnetoresistive effect elements 100 of the memory units MU0 to MU7.

Then, between time t3 and time t4 as shown in FIG. 8B, the write currents I for 1 write are supplied to only four memory units, i.e., the memory units MU1, MU3, MU5, and MU7 in which 1 is to be written. That is, while the write currents I for 0 write are kept supplied to the memory units MU0, MU2, MU4, and MU6 in which 0 is to be written, only the write currents I in the memory units MU1, MU3, MU5, and MU7 in which 1 is to be written are supplied in the opposite direction.

### [4-4] Reversing Current

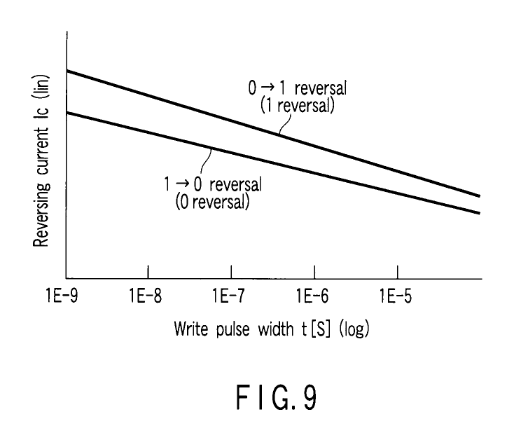

FIG. 9 shows the dependence of a reversing current on the write time in the magnetoresistive effect element according to the embodiment of the present invention. The dependence of a reversing current on the write time (the write pulse width) in 1 reversal and 0 reversal will be explained below.

As shown in FIG. 9, the experimental facts of a reversing current I_{C} are as follows.

(a) The reversing current I_{C} depends on a write pulse width t (the write time). The larger the pulse width t, the smaller the reversing current I_{C} in both 1 reversal and 0 reversal.

(b) A current value required for 0→1 reversal (1 reversal) differs from that required for 1→0 reversal (0 reversal). Generally, the reversing current I_{C} for 0 reversal is smaller than that for 1 reversal for the same write pulse width t.

Note that the reversing current I_{C} is indicated by

Ic=Ic0[1−(kT/E)ln(t/t0)] (1)

where I_{C}0 is a reversing current for 1 ns, k is a Boltzmann's constant, T is the absolute temperature, and t0=1 ns.

Feature (a) of the reversing current I_{C} described above shows that the reversing current I_{C} can be decreased by increasing the write current supply time (the write pulse width t). When compared to the reference example, therefore, the time of supply of the 1 write current to the memory units MU1, MU3, MU5, and MU7 in which 1 is to be written prolongs in write method example 1, and the time of supply of the 0 write current to the memory units MU0, MU2, MU4, and MU6 in which 0 is to be written prolongs in write method example 2. This makes it possible to decrease the reversing current I_{C} for 1 reversal in write method example 1, and the reversing current I_{C} for 0 reversal in write method example 2. Since this decreases a maximum value, which is determined by the gate of the selection transistor STr, of an electric current that can be supplied to the memory cell MC, it is possible to decrease the gate width W, and highly integrate the memory cells MC.

In addition, feature (2) of the reversing current I_{C} described above indicates that the reversing current I_{C} for 1 reversal is larger than that for 0 reversal for the same write pulse width t. Accordingly, the reversing currents I_{C} for 1 reversal and 0 reversal can be made almost equal by adjusting the 1 write current supply time in write method example 1 or the 0 write current supply time in write method example 2. For example, the reversing current I_{C} for 1 reversal can be decreased to be the same as that for 0 reversal by increasing the 1 write current supply time in write method example 1. This facilitates the circuit configuration.

### [5] Read Operation

A read operation of this embodiment uses the magnetoresistive effect.

A bit line and word line corresponding to a selected cell are selected, and the transistor STr of the selected cell is turned on. A read current is supplied to the selected magnetoresistive effect element 100. The resistance value of the magnetoresistive effect element 100 is read out on the basis of this read current, and whether the recorded state is “0” or “1” is determined by an amplifying operation performed via a sense amplifier.

Note that the read operation can be performed by reading out a current value by applying a constant voltage, or reading out a voltage value by supplying a constant electric current.

### [6] Effects

Before write data is determined, this embodiment starts supplying a write current in a first direction for writing first information (“1” or “0”) to both a first memory cell MC for writing the first information and a second memory cell MC for writing second information (“0” or “1”). After the write data is determined, the write current is kept supplied in the first direction to the first memory cell MC, and the write current changed in a second direction for writing the second information is supplied to the second memory cell MC.

Since the write current for writing the first information is kept supplied to the first memory cell MC before the write data is determined, the supply time of the write current for the first information can be increased. That is, as shown in FIG. 9, the reversing current I_{C} for the first information can be decreased because the write pulse width t can be increased. Since a maximum value of the electric current that can be supplied to the memory cell MC can be decreased, therefore, it is possible to decrease the gate width W of the transistor STr, and highly integrate the memory cells MC.

It is also possible to make the reversing currents I_{C} for “0” write and “1” write almost equal to each other by adjusting the write current supply time. This facilitates the circuit configuration.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A spin transfer torque magnetization switching type magnetic random access memory comprising:
a memory unit including a memory cell array having a first memory cell for writing first information and a second memory cell for writing second information; and
a controller connected to the memory unit, and configured to start supplying a write current in a first direction for writing the first information to the first memory cell and the second memory cell before a write data signal is determined, and, after the write data signal is determined, keep supplying the write current in the first direction to the first memory cell and supply the write current changed in a second direction for writing the second information to the second memory cell alone.

2. The memory according to claim 1, wherein a supply time of the write current in the first direction is longer than that of the write current in the second direction.

3. The memory according to claim 1, wherein for the same write pulse width, a value of a reversing current of the write current supplied in the second direction is smaller than that of a reversing current of the write current supplied in the first direction.

4. The memory according to claim 1, wherein the memory unit further includes a write driver circuit configured to receive the write data signal from the controller.

5. The memory according to claim 4, wherein the write driver circuit has a current source, a current sink, and a control circuit configured to exclusively validate the current source and the current sink.

6. The memory according to claim 1, wherein the write current supplied in the first direction has the same value as that of the write current supplied in the second direction.

7. The memory according to claim 1, wherein
the first memory cell and the second memory cell each include a magnetoresistive effect element having a fixed layer, a free layer, and an interlayer formed between the fixed layer and the free layer,
the first direction is a direction in which the write current flows from the fixed layer to the free layer, and
the second direction is a direction in which the write current flows from the free layer to the fixed layer.

8. The memory according to claim 1, wherein
the first memory cell and the second memory cell each include a magnetoresistive effect element having a fixed layer, a free layer, and an interlayer formed between the fixed layer and the free layer,
the first direction is a direction in which the write current flows from the free layer to the fixed layer, and
the second direction is a direction in which the write current flows from the fixed layer to the free layer.

9. The memory according to claim 1, wherein the first memory cell and the second memory cell each have a magnetoresistive effect element and a selection transistor connected in series.

10. The memory according to claim 1, wherein
the first memory cell and the second memory cell each include a magnetoresistive effect element having a fixed layer, a free layer, and an interlayer formed between the fixed layer and the free layer, and
magnetization directions in the fixed layer and the free layer are perpendicular to film surfaces.

11. A write method of a spin transfer torque magnetization switching type magnetic random access memory including:
a memory unit including a memory cell array having a first memory cell for writing first information and a second memory cell for writing second information; and
a controller connected to the memory unit,
the write method comprising:
starting supplying a write current in a first direction for writing the first information to the first memory cell and the second memory cell, before a write data signal is determined; and
after the write data signal is determined, keeping supplying the write current in the first direction to the first memory cell, and supplying the write current changed in a second direction for writing the second information to the second memory cell alone.

12. The method according to claim 11, wherein a supply time of the write current in the first direction is longer than that of the write current in the second direction.

13. The method according to claim 11, wherein for the same write pulse width, a value of a reversing current of the write current supplied in the second direction is smaller than that of a reversing current of the write current supplied in the first direction.

14. The method according to claim 11, wherein the memory unit further includes a write driver circuit configured to receive the write data signal from the controller.

15. The method according to claim 14, wherein the write driver circuit has a current source, a current sink, and a control circuit configured to exclusively validate the current source and the current sink.

16. The method according to claim 11, wherein the write current supplied in the first direction has the same value as that of the write current supplied in the second direction.

17. The method according to claim 11, wherein
the first memory cell and the second memory cell each include a magnetoresistive effect element having a fixed layer, a free layer, and an interlayer formed between the fixed layer and the free layer,
the first direction is a direction in which the write current flows from the fixed layer to the free layer, and
the second direction is a direction in which the write current flows from the free layer to the fixed layer.

18. The method according to claim 11, wherein
the first memory cell and the second memory cell each include a magnetoresistive effect element having a fixed layer, a free layer, and an interlayer formed between the fixed layer and the free layer,
the first direction is a direction in which the write current flows from the free layer to the fixed layer, and
the second direction is a direction in which the write current flows from the fixed layer to the free layer.

19. The method according to claim 11, wherein the first memory cell and the second memory cell each have a magnetoresistive effect element and a selection transistor connected in series.

20. The method according to claim 11, wherein
the first memory cell and the second memory cell each include a magnetoresistive effect element having a fixed layer, a free layer, and an interlayer formed between the fixed layer and the free layer, and
magnetization directions in the fixed layer and the free layer are perpendicular to film surfaces.
